(19) United States
(12) Patent Application Publication
(10) Pub. No.: US 2025/0176226 A1
(43) Pub. Date: May 29, 2025

(54) SEMICONDUCTOR DEVICE INCLUDING TWO-DIMENSIONAL MATERIAL AND MANUFACTURING METHOD THEREOF

(71) Applicant: Samsung Electronics Co., Ltd., Suwon-si (KR)

(72) Inventors: Hyeon Cheol PARK, Suwon-si (KR); Huije RYU, Suwon-si (KR); Kyung-Eun BYUN, Suwon-si (KR); Minsu SEOL, Suwon-si (KR); Joungeun YOO, Suwon-si (KR); Eunkyu LEE, Suwon-si (KR); Yeonchoo CHO, Suwon-si (KR)

(73) Assignee: Samsung Electronics Co., Ltd., Suwon-si (KR)

(21) Appl. No.: 18/890,051

(22) Filed: Sep. 19, 2024

(30) Foreign Application Priority Data
Nov. 23, 2023 (KR) 10-2023-0164856

(51) Int. Cl. H01L 29/76; H01L 21/02; H01L 21/443; H01L 29/24; H01L 29/49; H01L 29/66; H01L 29/786

(52) U.S. Cl. CPC H10D 48/362; H01L 21/02568; H01L 21/443; H10D 30/6739; H10D 30/6757; H10D 62/80; H10D 99/00

(57) ABSTRACT

Provided are a semiconductor device including a two-dimensional material and a manufacturing method thereof. The semiconductor device includes a channel layer containing a two-dimensional semiconductor material, a source electrode and a drain electrode provided on both sides of the channel layer, respectively, a gate insulating layer provided on the channel layer between the source electrode and the drain electrode and including a two-dimensional insulating material, an interlayer provided between the channel layer and the gate insulating layer, and a gate electrode provided on the gate insulating layer.

### CROSS-REFERENCE TO RELATED APPLICATION

This application is based on and claims priority under 35 U.S.C. § 119 to Korean Patent Application No. 10-2023-0164856, filed on Nov. 23, 2023, in the Korean Intellectual Property Office, the disclosure of which is incorporated by reference herein in its entirety.

### BACKGROUND

### 1. Field

Inventive concepts relate to semiconductor devices including a two-dimensional material and manufacturing methods thereof.

### 2. Description of the Related Art

Transistors are semiconductor devices that serve an electrical switching role and are used in various semiconductor products such as memory and driving integrated circuits (ICs). When the size of the semiconductor device is reduced, the number of semiconductor devices that can be integrated on one wafer increases and the driving speed of the semiconductor device is increased, and thus, research is being actively conducted to reduce the size of the semiconductor device.

Recently, research using a two-dimensional material has been conducted to reduce the size of a semiconductor device. Two-dimensional materials are in the spotlight as materials that can overcome the limitations of performance degradation due to the decrease in the size of semiconductor devices because they are stable and have excellent properties even at a small thickness of 1 nm or less.

### SUMMARY

Provided are semiconductor devices including a two-dimensional material and a manufacturing method thereof.

Additional aspects will be set forth in part in the description which follows and, in part, will be apparent from the description, or may be learned by practice of the presented example embodiments of inventive concepts.

According to an example embodiment, a semiconductor device may include a channel layer including a two-dimensional semiconductor material, a source electrode and a drain electrode spaced apart from each other on the channel layer, a gate insulating layer on the channel layer, and the gate insulating layer including a two-dimensional insulating material, an interlayer between the channel layer and the gate insulating layer, and a gate electrode on the gate insulating layer.

The two-dimensional semiconductor material may include a transition metal dichalcogenide.

The transition metal dichalcogenide may include a metal element selected from the group consisting of Mo, W, Nb, V, Ta, Ti, Zr, Hf, Tc, and Re, and a chalcogen element selected from the group consisting of S, Se, and Te.

The two-dimensional insulating material may include Ca₂(Nb₍₁₋ₓ₎ Taₓ)₃O₁₀ (0.3≤x≤1).

The two-dimensional insulating material may include Sr₂(Nb₍₁₋ₓ₎Taₓ)₃O₁₀ (0.3≤x≤1).

The interlayer may include at least one of transition metal oxide or transition metal sulfide.

The transition metal oxide may include oxide of an element selected from the group consisting of Nb, Ta, Mo, and W.

The transition metal sulfide may include sulfide of an element selected from the group consisting of Nb, Ta, Mo, and W.

A thickness of the interlayer may be in a range of about 0.1 nm to about 5 nm.

The interlayer may include 1 to 10 layers.

The interlayer may include a first layer adjacent to the channel layer and including transition metal sulfide and a second layer adjacent to the gate insulating layer and including transition metal oxide.

The gate electrode may be on at least one of an upper portion or a lower portion of the channel layer.

According to an example embodiment, an electronic device including the semiconductor device described above may be provided.

According to an example embodiment, a method of manufacturing a semiconductor device may include forming a channel layer, the channel layer including a two-dimensional semiconductor material, forming an interlayer on the channel layer, forming a gate insulating layer on the interlayer, the gate insulating material including a two-dimensional insulating material, forming a gate electrode on the gate insulating layer, and forming a source electrode and a drain electrode spaced apart from each other on the channel layer.

The two-dimensional semiconductor material may include transition metal dichalcogenide.

The two-dimensional insulating material may include Ca₂(Nb₍₁₋ₓ₎Taₓ)₃O₁₀ (0.3≤x≤1).

The two-dimensional insulating material may include Sr₂(Nb₍₁₋ₓ₎Taₓ)₃O₁₀ (0.3≤x≤1).

The interlayer may include at least one of transition metal oxide or transition metal sulfide.

A thickness of the interlayer may be in a range of about 0.1 nm to about 5 nm.

The forming of the interlayer may include forming a first layer on the channel layer, the first layer including transition metal sulfide, and forming a second layer on the first layer, the second layer including transition metal oxide.

### BRIEF DESCRIPTION OF THE DRAWINGS

The above and other aspects, features, and advantages of certain example embodiments of inventive concepts will be more apparent from the following description taken in conjunction with the accompanying drawings, in which:

FIG. 1 is a cross-sectional view illustrating a semiconductor device according to an example embodiment;

FIG. 2 is a cross-sectional view of the interlayer of FIG. 1 according to an example embodiment;

FIG. 3 is a cross-sectional view of the interlayer of FIG. 1 according to an example embodiment;

FIGS. 4 to 7 are cross-sectional views for describing a method of manufacturing a semiconductor device according to an example embodiment;

FIG. 8 is a cross-sectional view illustrating a semiconductor device according to an example embodiment;

FIG. 9 is a perspective view illustrating a semiconductor device according to an example embodiment;

FIG. 10 is a cross-sectional view taken along a line A-A′ of FIG. 9;

FIG. 11 is a perspective view illustrating a semiconductor device according to an example embodiment;

FIG. 12 is a cross-sectional view taken along a line B-B′ of FIG. 11; and

FIGS. 13 and 14 are conceptual block diagrams schematically illustrating a device architecture applicable to an electronic device according to some example embodiments.

### DETAILED DESCRIPTION

Reference will now be made in detail to example embodiments, examples of which are illustrated in the accompanying drawings, wherein like reference numerals refer to like elements throughout. In this regard, the present example embodiments may have different forms and should not be construed as being limited to the descriptions set forth herein. Accordingly, the example embodiments are merely described below, by referring to the figures, to explain aspects of inventive concepts. As used herein, the term “and/or” includes any and all combinations of one or more of the associated listed items. Expressions such as “at least one of,” when preceding a list of elements, modify the entire list of elements and do not modify the individual elements of the list.

Hereinafter, some example embodiments will be described in detail with reference to the accompanying drawings. In the following drawings, the same reference numerals refer to the same components, and the size of each component in the drawings may be exaggerated for clarity and convenience of description. Meanwhile, the example embodiments described below are merely illustrative, and various modifications are possible from these example embodiments.

Hereinafter, the term “upper portion” or “on” may also include “to be present on the top, bottom, left or right portion on a non-contact basis” as well as “to be present just on the top, bottom, left or right portion in directly contact with”. Singular expressions include plural expressions unless the context clearly means otherwise. In addition, when a part “contains” a component, this means that it may contain other components, rather than excluding other components, unless otherwise stated.

The use of the term “the” and similar indicative terms may correspond to both singular and plural. Unless there is a clear order or contrary description of the steps constituting the method, these steps may be performed in the appropriate order, and are not necessarily limited to the order described.

Further, the terms “unit”, “module” or the like mean a unit that processes at least one function or operation, which may be implemented in hardware or software or implemented in a combination of hardware and software.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

The connection or connection members of lines between the components shown in the drawings exemplarily represent functional connection and/or physical or circuit connections, and may be replaceable or represented as various additional functional connections, physical connections, or circuit connections in an actual device.

The use of all examples or illustrative terms is simply to describe technical ideas in detail, and the scope is not limited due to these examples or illustrative terms unless the scope is limited by the claims.

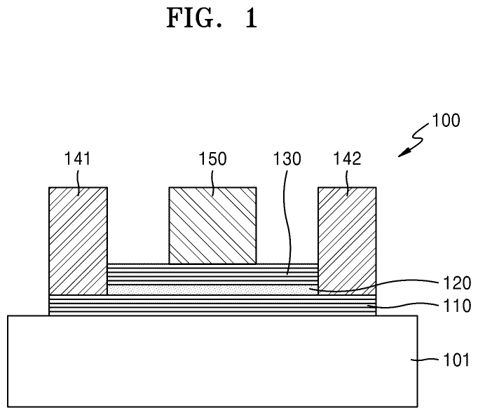

FIG. 1 is a cross-sectional view illustrating a semiconductor device 100 according to an example embodiment. A semiconductor device 100 shown in FIG. 1 may include, for example, a field effect transistor (FET).

Referring to FIG. 1, a channel layer 110 is provided on a substrate 101. The substrate 101 may include various materials, such as a semiconductor material, an insulating material, a metal material, and/or the like, but example embodiments are not limited thereto. The substrate 101 may be, for example, a substrate for growing a two-dimensional semiconductor material of the channel layer 110 to be described later.

The channel layer 110 may include a two-dimensional semiconductor material. The two-dimensional semiconductor material refers to a two-dimensional material having a layered structure in which constituent atoms are two-dimensionally coupled. The two-dimensional semiconductor material may have improved or excellent electrical properties and may maintain high mobility without greatly changing its characteristics even when the thickness is reduced to nanoscale.

The two-dimensional semiconductor material may include, for example, a transition metal dichalcogenide (TMD). However, example embodiments are not limited thereto.

The TMD is a two-dimensional material having semiconductor properties and is a compound including a transition metal element and a chalcogen element. For example, the transition metal element may include, for example, at least one of Mo, W, Nb, V, Ta, Ti, Zr, Hf, Co, Tc, or Re, and the chalcogen element may include, for example, at least one of S, Se, or Te. For example, the TMD may include, for example, MoS₂, MoSe₂, MoTe₂, WS₂, WSe₂, WTe₂, ZrS₂, ZrSe₂, HfS₂, HfSe₂, NbSe₂, ReSe₂, and the like. However, example embodiments are not limited thereto.

A source electrode 141 and a drain electrode 142 may be provided at both sides of the channel layer 110, respectively. A gate insulating layer 130 may be provided above the channel layer 110 between the source electrode 141 and the drain electrode 142. A gate electrode 150 may be provided on the gate insulating layer 130.

The gate insulating layer 130 may include a two-dimensional insulating material. The two-dimensional insulating material may include, for example, Ca₂(Nb₍₁₋ₓ₎Taₓ)₃O₁₀ (where 0.3≤x≤1). The two-dimensional insulating material may include, for example, Sr₂Nb₍₁₋ₓ₎ Taₓ)₃O₁₀ (where 0.33≤x≤1). When the gate insulating layer 130 includes a material having a small band gap, there may be a problem that an on/off current ratio (Iₒₙ/I_{off}) becomes small. In some example embodiments of present inventive concepts, the two-dimensional insulating material used for the gate insulating layer 130 may include Ta having a large band gap, thereby improving an on-off current ratio (Iₒₙ/I_{off}) and improving a subthreshold swing (SS) characteristic.

A thickness of the gate insulating layer 130 may be, for example, approximately 5 nm or less. For example, a thickness of the gate insulating layer 130 may be in a range of about 0.5 nm to about 3 nm. Because the gate insulating layer 130 may include a two-dimensional insulating material, a higher dielectric constant and/or an improved or excellent insulating property may be achieved even at a thin thickness of about 5 nm or less. In addition, the two-dimensional insulating material of the gate insulating layer 130 may be provided to cover the channel layer 110, thereby reducing damage to the channel layer 110.

The gate electrode 160 may include, for example, one or metal materials and/or conductive oxides. For example, the metallic material may include, for example, at least one selected from the group consisting of Au, Ti, TiN, TaN, W, Mo, WN, Pt, and Ni. In addition, the conductive oxide may include, for example, Indium Tin Oxide (ITO), Indium Zinc Oxide (IZO), etc. However, this is merely illustrative, and example embodiments are not limited thereto.

An interlayer 120 may be provided between the channel layer 110 and the gate insulating layer 130. A thickness of the interlayer 120 may be, for example, approximately 5 nm or less. For example, a thickness of the interlayer 130 may be in a range of about 0.1 nm to about 5 nm, but example embodiments are not limited thereto. The interlayer 120 may include, for example, at least one of transition metal oxide or transition metal sulfide. The transition metal sulfide may include, for example, sulfide of one element selected from the group consisting of Nb, Ta, Mo, and W. For example, the interlayer 120 may include (Nb, Ta, Mo, W)Sₓ (1≤x≤2). However, example embodiments are not limited thereto. In addition, the transition metal oxide may include, for example, oxide of one element selected from the group consisting of Nb, Ta, Mo, and W. For example, the transition metal oxide may include (Nb, Ta, Mo, W)Oₓ (1≤x≤2). However, example embodiments are not limited thereto.

Accordingly, by forming the interlayer 120 including, for example, sulfide and oxide between the channel layer 110 including a two-dimensional semiconductor material and the gate insulating layer 130 including a two-dimensional insulating material, the bonding force between the channel layer 110 and the gate insulating layer 130 may be improved. In addition, defects in the surface of the channel layer 110 may be prevented by the interlayer 120, and the performance of the semiconductor device 100 (e.g., the subthreshold swing (SS), the on/off current ratio (Iₒₙ/I_{off}), etc.) may be improved.

The source electrode 141 and the drain electrode 142 may be provided at both sides of the gate electrode 150, respectively. The source electrode 141 and the drain electrode 142 may be provided in and/or on a source region and a drain region of the channel layer 110, respectively. For example, the source electrode 141 may be provided to be in contact with the source region of the channel layer 110, and the drain electrode 142 may be provided to be in contact with the drain region of the channel layer 110. The source electrode 141 and the drain electrode 142 may include, for example, a metal material having excellent electrical conductivity, such as, for example, Ag, Au, Pt, or Cu, but example embodiments are not limited thereto.

In conventional silicon-based semiconductor devices, as channel thickness decreases, mobility decreases and threshold voltage distribution increases, and as channel length decreases, performance degradation due to the short channel effect increases, so there is a limit to reducing the size of semiconductor devices.

In the semiconductor device 100 according to the example embodiments, the channel layer 110, including a two-dimensional semiconductor material, may have improved or excellent performance even with a thin thickness of 1 nm or less, and may also have a reduced short channel effect, thereby overcoming limitations of performance degradation due to decreased size of the semiconductor device 100.

In the semiconductor device 100 according to the example embodiments, an on/off current ratio (Iₒₙ/I_{off}) may be improved by including Ta in which the two-dimensional insulating material of the gate insulating layer 130 has a large band gap. Since the gate insulating layer 130 includes a two-dimensional insulating material, a higher dielectric constant and/or an improved or excellent insulating property may be acquired even at a thin thickness of about 5 nm or less. In addition, the two-dimensional insulating material of the gate insulating layer 130 may be provided to cover the channel layer 110, thereby reducing damage to the channel layer 110.

In the semiconductor device 100 according to example embodiments, an interlayer 120 including sulfide and oxide may be provided between the channel layer 110 including a two-dimensional semiconductor material and the gate insulating layer 130 including a two-dimensional insulating material, thereby improving the bonding force between the channel layer 110 and the gate insulating layer 130. In addition, defects in the surface of the channel layer 110 may be reduced or prevented by the interlayer 120, and the performance of the semiconductor device 100 (e.g., the subthreshold swing (SS), the on/off current ratio (Iₒₙ/I_{off}), etc.) may be improved.

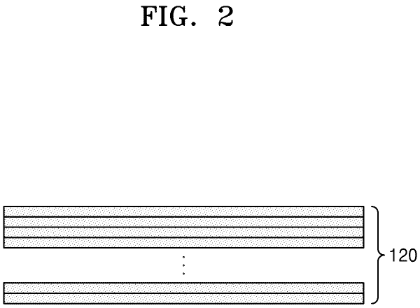

FIG. 2 is a cross-sectional view of the interlayer of FIG. 1 according to an example embodiment.

Referring to FIG. 2, the interlayer 120 may include a plurality of layers. For example, the interlayer 120 may include, for example, two to ten layers. For example, a thickness of the interlayer 120 may be in a range of about 0.1 nm to about 5 nm.

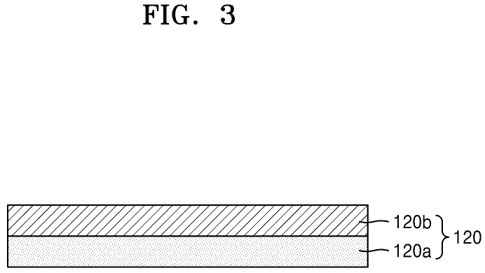

FIG. 3 is a cross-sectional view of the interlayer of FIG. 1 according to an example embodiment.

Referring to FIG. 3, the interlayer 120 may include, for example, a first layer 120a and a second layer 120b, and the first layer 120a and the second layer 120b may include a same material or different materials from each other. For example, the first layer 120a may include, for example, sulfide, and the second layer 120b may include, for example, oxide, but example embodiments are not limited thereto. The first layer 120a may be, for example, provided close to the channel layer 110, and the second layer 120b may be provided close to the gate insulating layer 130.

For example, when the channel layer 110 includes MoS₂, and the gate insulating layer 130 includes (Ca, Sr)₂ (Nb₍₁₋ₓ₎Taₓ)₃O₁₀ (0.33≤x≤1), the first layer 120a of the interlayer 120 may be provided close to the channel layer 110 including, for example, sulfur, and the second layer 120b of the interlayer 120 is provided close to the gate electrode 150 including, for example, oxygen, thereby improving bonding at the interface between the channel layer 110 and the gate electrode 150.

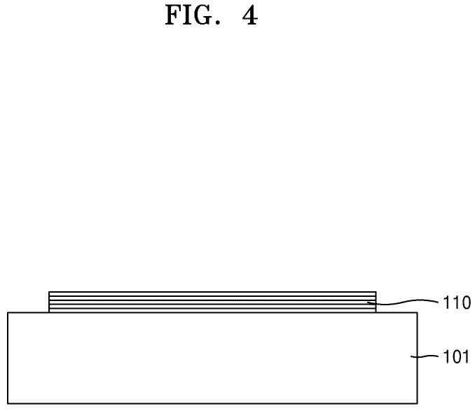

Hereinafter, a method of manufacturing the semiconductor device 100 according to the example embodiments described above will be described. FIGS. 4 to 7 are cross-sectional views for describing a method of manufacturing a semiconductor device according to an example embodiment.

Referring to FIG. 4, a channel layer 110 is formed on the substrate 101. The substrate 101 may include, for example, various materials, such as a semiconductor material, an insulating material, a metal material, and/or the like. For example, the channel layer 110 may include a two-dimensional semiconductor material. The channel layer 110 may be formed, for example, by depositing and growing a two-dimensional semiconductor material on a surface of the substrate 101. The deposition of a two-dimensional semiconductor material may be performed by, for example, chemical vapor deposition (CVD), physical vapor deposition (PVD), and/or the like, but example embodiments are not limited thereto.

The TMD is a two-dimensional material having semiconductor properties and is a compound of a transition metal and a chalcogen element. Here, the transition metal may include, for example, at least one of Mo, W, Nb, V, Ta, Ti, Zr, Hf, Co, Tc, or Re, and the chalcogen element may include, for example, at least one of S, Se, or Te. For example, the TMD may include MoS₂, MoSe₂, MoTe₂, WS₂, WSe₂, WTe₂, ZrS₂, ZrSe₂, HfS₂, HfSe₂, NbSe₂, ReSe₂, and/or the like. However, example embodiments are not limited thereto.

The channel layer 110 may have, for example, a single-layer structure, or multi-layer structure wherein each layer may have an atomic level thickness. The channel layer 110 may include, for example, 1 to 10 layers. For example, the channel layer 110 may include one to five layers. However, example embodiments are not limited thereto.

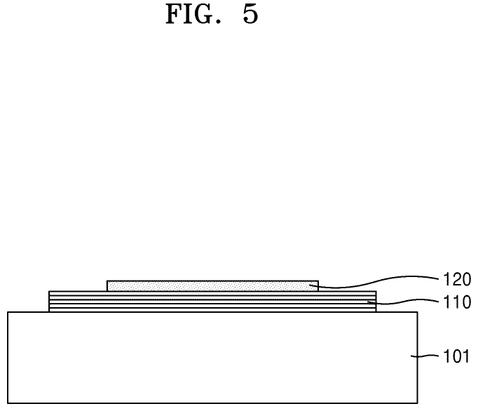

Referring to FIG. 5, an interlayer 120 may be deposited on a desired (or alternatively, predetermined) portion of the channel layer 110. A thickness of the interlayer 120 may be, for example, in a range of about 0.1 nm to about 5 nm. The interlayer 120 may include, for example, at least one of transition metal oxide or transition metal sulfide, but example embodiments are not limited thereto. The transition metal sulfide may include, for example, sulfide of one element selected from the group consisting of Nb, Ta, Mo, and W. For example, the interlayer 120 may include (Nb, Ta, Mo, W)Sₓ (1≤x≤2), but is not limited thereto. In addition, the transition metal oxide may include, for example, oxide of one element selected from the group consisting of Nb, Ta, Mo, and W. For example, the transition metal oxide may include (Nb, Ta, Mo, W)Oₓ (1≤x≤2), but is not limited thereto. The interlayer 120 may be formed by stacking a first layer including a transition metal sulfide on the channel layer 110 and a second layer including a transition metal oxide on the first layer, but example embodiments are not limited thereto.

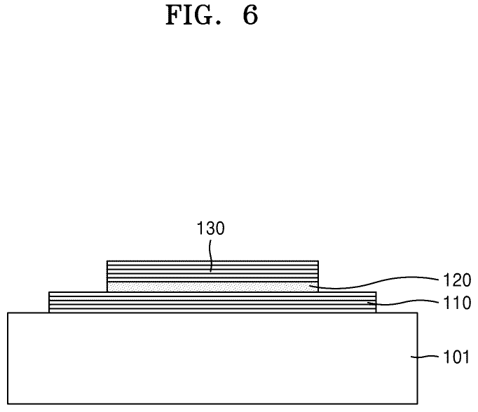

Referring to FIG. 6, a gate insulating layer 130 may be deposited on the interlayer 120. The gate insulating layer 130 may include a two-dimensional insulating material. The two-dimensional insulating material may include, for example, Ca₂(Nb₍₁₋ₓ₎Taₓ)₃O₁₀ (0.3≤x≤1) or Sr₂(Nb₍₁₋ₓ₎Taₓ)₃O₁₀ (0.33≤x≤1). The two-dimensional insulating material used for the gate insulating layer 130 may include Ta having a large band gap, thereby improving an on-off current ratio (Iₒₙ/I_{off}) and improving a subthreshold swing (SS) characteristic. A thickness of the gate insulating layer 130 may be in a range of about 0.5 nm to about 5 nm, but example embodiments are not limited thereto. For example, a thickness of the gate insulating layer 130 may be in a range of about 0.5 nm to about 3 nm. The two-dimensional insulating material may be formed, for example, through a process of synthesizing a parental phase having a layered structure and exfoliating the synthesized parental phase, but example embodiments are not limited thereto.

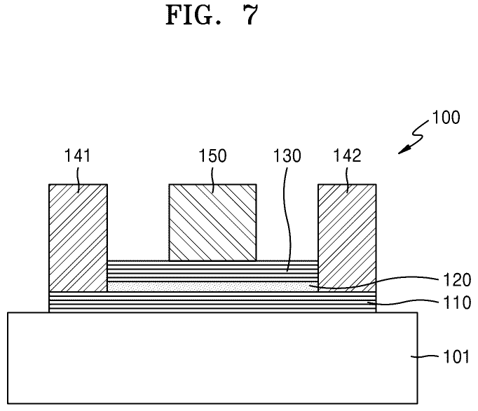

Referring to FIG. 7, a gate electrode 150 may be deposited on the gate insulating layer 130, and a source electrode 141 and a drain electrode 142 may be deposited on both sides of the channel layer 110, respectively. The gate electrode 150 may be provided on an upper portion of the gate insulating layer 130. The source electrode 141 and the drain electrode 142 may be provided in a source region and a drain region of the channel layer 110, respectively. The source electrode 141 may be provided to be in contact with the source region of the channel layer 110, and the drain electrode 142 may be provided to be in contact with the drain region of the channel layer 110.

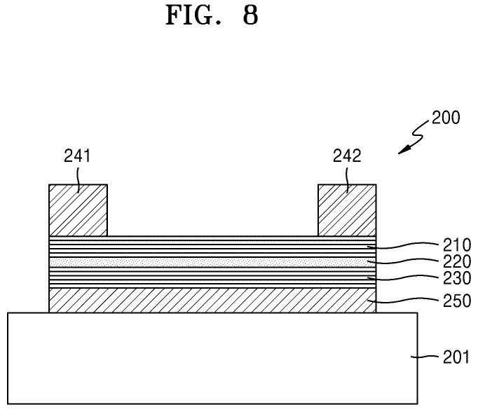

FIG. 8 is a cross-sectional view illustrating a semiconductor device 200 according to an example embodiment. Hereinafter, the differences from the example embodiments described above will be mainly described.

Referring to FIG. 8, a gate electrode 250 may be provided below a channel layer 210. The gate electrode 250 may be provided on the substrate 201. A gate insulating layer 230, an interlayer 220, and a channel layer 210 may be sequentially stacked on the gate electrode 250. A source electrode 241 and a drain electrode 242 may be provided at both sides of the channel layer 210, respectively. Since each component has been described above, a detailed description thereof will be omitted.

For example, a semiconductor device 100 having a top gate structure in which a gate electrode is provided on an upper part of the channel layer and a semiconductor device 200 having a bottom gate structure in which a gate electrode is provided on a lower part of the channel layer have been described, but example embodiments are not limited thereto. For example, a semiconductor device with a double gate structure in which gate electrodes are provided in upper and lower parts of the channel layer, respectively, may also be implemented.

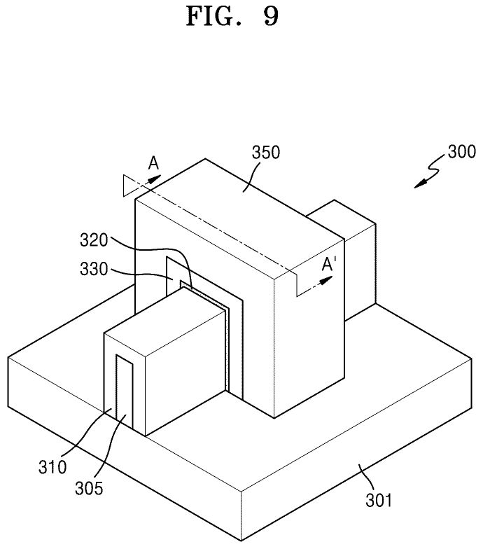

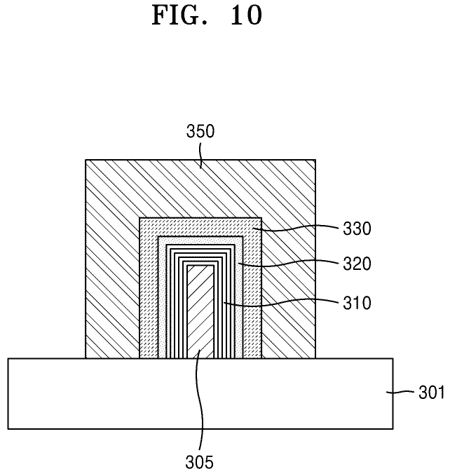

FIG. 9 is a perspective view illustrating a semiconductor device 300 such as a fin field effect transistor (FinFET) according to an example embodiment, and FIG. 10 is a cross-sectional view taken along line A-A′ of FIG. 9.

Referring to FIGS. 9 and 10, an insulator 305 is provided perpendicular to the substrate 301, and a channel layer 310 covers the insulator 305. Here, the channel layer 310 may have a fin shape.

The channel layer 310 may include a two-dimensional semiconductor material. Because the channel layer 310 has been described above, a detailed description thereof will be omitted.

A gate insulating layer 330 may be provided on the channel layer 310. The gate insulating layer 330 may surround three surfaces of the channel layer 310. The gate insulating layer 330 may include a two-dimensional insulating material. Since the gate insulating layer 330 has been described above, a detailed description thereof will be omitted.

A gate electrode 350 may be provided on the gate insulating layer 330. The gate electrode 350 may surround three surfaces of the gate insulating layer 330. Meanwhile, although not shown in the drawings, source and drain electrodes may be provided on both sides of the channel layer 110, respectively.

An interlayer 320 may be provided between the channel layer 310 and the gate insulating layer 330. The interlayer 320 may include, for example, sulfide and/or oxide. Since the interlayer 320 has been described above, a detailed description thereof will be omitted.

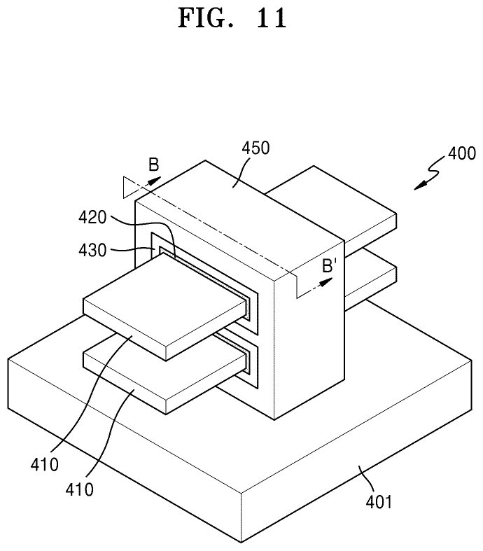

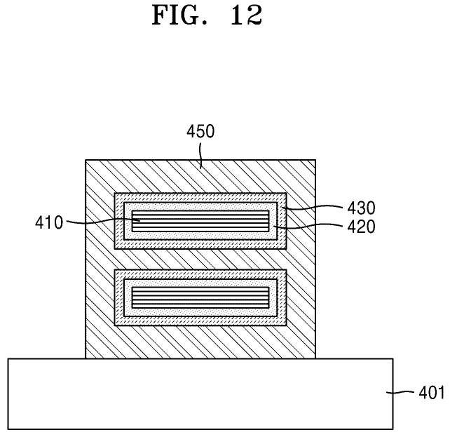

FIG. 11 is a perspective view illustrating a semiconductor device 400 such as a multi-bridge channel field effect transistor (MBCFET) according to an example embodiment, and FIG. 12 is a cross-sectional view taken along line B-B′ of FIG. 11.

Referring to FIGS. 11 and 12, at least one channel layer 410 may be arranged on a substrate 401 to be spaced apart from the substrate 401. Here, each channel layer 410 may have a shape of a sheet or a shape similar to a sheet that is arranged parallel to the substrate 401. FIGS. 11 and 12 illustrate a case where two channel layers 410 are arranged vertically above the substrate 401 and spaced apart from each other.

Each channel layer 410 may include a two-dimensional semiconductor material.

Because the channel layer 410 has been described above, a detailed description thereof will be omitted.

A gate insulating layer 430 may be provided on the channel layer 410. The gate insulating layer 430 may surround four surfaces of the channel layer 410. The gate insulating layer 430 may include a two-dimensional insulating material. Because the gate insulating layer 430 has been described above, a detailed description thereof will be omitted.

A gate electrode 450 may be provided on the gate insulating layer 430. The gate electrode 450 may surround four surfaces of the gate insulating layer 430. Although not shown in the drawings, the source and drain electrodes may be provided on both sides of the channel layer 410, respectively.

An interlayer 420 may be provided between the channel layer 410 and the gate insulating layer 430. The interlayer 420 may surround four surfaces of the channel layer 410, and the gate insulating layer 430 may surround four surfaces of the interlayer 420. The interlayer 420 may include, for example, at least one of sulfide or oxide. Because the interlayer 420 has been described above, a detailed description thereof will be omitted.

Meanwhile, an insulator (not shown) may be arranged in parallel with the substrate 401 on the upper part of the substrate 401, and a channel layer 410 may be provided to surround the insulator.

The semiconductor devices 100 to 400 described above may be applied to memory devices such as, for example, dynamic random access memory (DRAM) devices. The memory devices may have a structure in which, for example, the semiconductor devices 100 to 400 and capacitors are electrically connected. In addition, the semiconductor devices 100 to 400 may be applied to various electronic devices. For example, the semiconductor devices 100 to 400 described above may be used for arithmetic operations, program execution, temporary data retention, etc. in electronic devices such as mobile devices, computers, laptops, sensors, network devices, neuromorphic devices, etc., but example embodiments are not limited thereto.

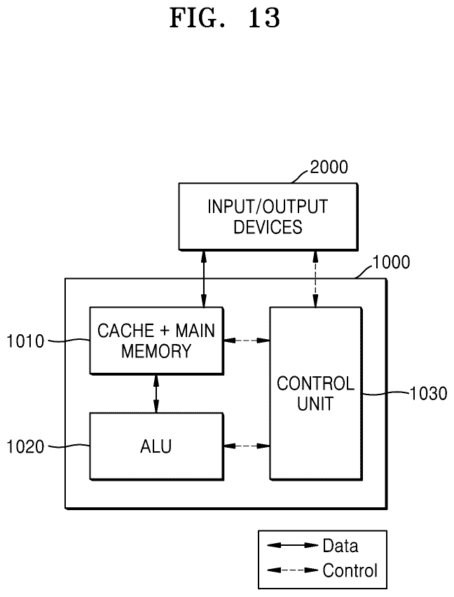

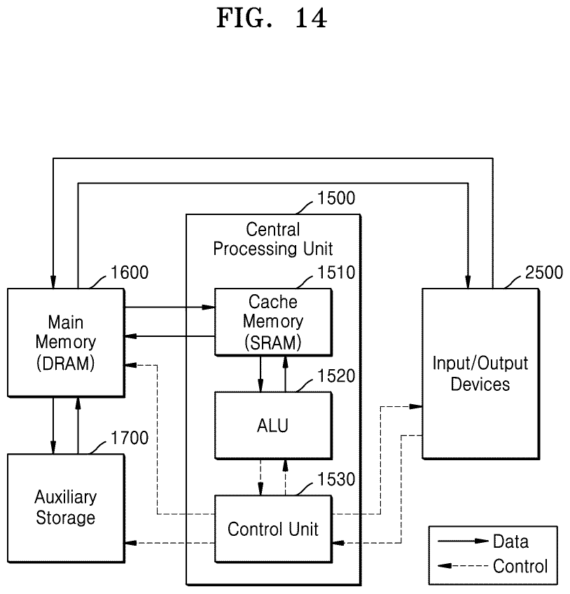

FIGS. 13 and 14 are conceptual block diagrams schematically illustrating an electronic device architecture applicable to an electronic device according to some example embodiments.

Referring to FIG. 13, an electronic device architecture 1000 may include, for example, a memory unit 1010, an architectural logical unit (ALU) 1020, and a control unit 1030. The memory unit 10, the ALU 1020, and the control unit 10 may be, for example, electrically connected to each other. For example, the electronic device architecture 1000 may be implemented as a single chip including the memory unit 1010, the ALU 1020, and the control unit 1030, but example embodiments are not limited thereto.

For example, the memory unit 1010, the ALU 1020, and the control unit 1030 may be interconnected by, for example, metal lines in an on-chip to directly communicate with each other. The memory unit 1010, the ALU 1020, and the control unit 1030 may be, for example, monolithically integrated on one substrate to form one chip, but example embodiments are not limited thereto. Input/output devices 2000 may be, for example, connected to the electronic device architecture (chip) 1000.

Each of the ALU 1020 and the control unit 1030 may, for example, independently include the semiconductor devices 100 to 400 described above, and the memory unit 1010 may include the semiconductor devices 100 to 400, capacitors, or a combination thereof. The memory unit 1010 may include, for example, both a main memory and a cache memory. The electronic device architecture (chip) 1000 may be an on-chip memory processing unit, but example embodiments are not limited thereto.

Referring to FIG. 14, a cache memory 1510, an ALU 1520, and a control unit 1530 may constitute a central processing unit (CPU) 1500. The cache memory 1510 may include, for example, a static random access memory (SRAM), and may include the semiconductor devices 100 to 400 described above. Apart from the CPU 1500, a main memory 1600 and an auxiliary storage 1700 may be provided. The main memory 1600 may include, for example, a DRAM device, but example embodiments are not limited thereto.

In some cases, for example, the electronic device architecture may be implemented in a form in which computing unit elements and memory unit elements are adjacent to each other in one chip without division of sub-units.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

According to the disclosed example embodiments, because the two-dimensional insulating material used in the gate insulating layer includes Ta with a large band gap, an on/off current ratio (Iₒₙ/I_{off}) may be improved, and the two-dimensional insulating material has a thin thickness of about 5 nm or less, semiconductor devices having a higher dielectric constant and/or improved or excellent insulating properties may be implemented.

In addition, according to example embodiments, an interlayer including sulfide and/or oxide may be provided between a channel layer including a two-dimensional semiconductor material and a gate insulating layer including a two-dimensional insulating material to improve the bonding strength between the channel layer and the gate insulating layer.

It should be understood that some example embodiments described herein should be considered in a descriptive sense only and not for purposes of limitation. Descriptions of features or aspects within each example embodiment should typically be considered as available for other similar features or aspects in other example embodiments. While one or more example embodiments have been described with reference to the figures, it will be understood by those of ordinary skill in the art that various changes in form and details may be made therein without departing from the spirit and scope as defined by the following claims.

What is claimed is:

1. A semiconductor device comprising:
a channel layer including a two-dimensional semiconductor material;
a source electrode and a drain electrode spaced apart from each other on the channel layer;
a gate insulating layer on the channel layer, and the gate insulating layer including a two-dimensional insulating material;
an interlayer between the channel layer and the gate insulating layer; and
a gate electrode on the gate insulating layer.

2. The semiconductor device of claim 1, wherein the two-dimensional semiconductor material comprises transition metal dichalcogenide.

3. The semiconductor device of claim 2, wherein the transition metal dichalcogenide comprises a metal element selected from the group consisting of Mo, W, Nb, V, Ta, Ti, Zr, Hf, Tc, and Re, and a chalcogen element selected from the group consisting of S, Se, and Te.

4. The semiconductor device of claim 1, wherein the two-dimensional insulating material comprises Ca₂(Nb₍₁₋ₓ₎Taₓ)₃O₁₀ (0.33≤x≤1).

5. The semiconductor device of claim 1, wherein the two-dimensional insulating material comprises Sr₂(Nb₍₁₋ₓ₎Taₓ)₃O₁₀ (0.3≤x≤1).

6. The semiconductor device of claim 1, wherein the interlayer comprises at least one of transition metal oxide or transition metal sulfide.

7. The semiconductor device of claim 6, wherein the transition metal oxide includes oxide of an element selected from the group consisting of Nb, Ta, Mo, and W.

8. The semiconductor device of claim 6, wherein the transition metal sulfide includes sulfide of an element selected from the group consisting of Nb, Ta, Mo, and W.

9. The semiconductor device of claim 1, wherein a thickness of the interlayer is in a range of about 0.1 nm to about 5 nm.

10. The semiconductor device of claim 1, wherein the interlayer comprises 1 to 10 layers.

11. The semiconductor device of claim 1, wherein the interlayer includes a first layer adjacent to the channel layer, the first layer including transition metal sulfide, and a second layer adjacent to the gate insulating layer, the second layer including transition metal oxide.

12. The semiconductor device of claim 1, wherein the gate electrode is on at least one of an upper portion or a lower portion of the channel layer.

13. An electronic device comprising the semiconductor device according to claim 1.

14. A method of manufacturing a semiconductor device comprising:
forming a channel layer, the channel layer including a two-dimensional semiconductor material;
forming an interlayer on the channel layer;
forming a gate insulating layer on the interlayer, the gate insulating layer including a two-dimensional insulating material;
forming a gate electrode on the gate insulating layer; and
forming a source electrode and a drain electrode spaced apart from each other on the channel layer.

15. The method of claim 14, wherein the two-dimensional semiconductor material includes transition metal dichalcogenide.

16. The method of claim 14, wherein the two-dimensional insulating material comprises Ca₂(Nb₍₁₋ₓ₎Taₓ)₃O₁₀ (0.33≤x≤1).

17. The method of claim 14, wherein the two-dimensional insulating material comprises Sr₂(Nb₍₁₋ₓ₎Taₓ)₃O₁₀ (0.3≤x≤1).

18. The method of claim 14, wherein the interlayer comprises at least one of transition metal oxide or transition metal sulfide.

19. The method of claim 14, wherein a thickness of the interlayer is in a range of about 0.1 nm to about 5 nm.

20. The method of claim 14, wherein the forming of the interlayer comprises forming a first layer on the channel layer, the first layer including a transition metal sulfide, and forming a second layer on the first layer, the second layer including a transition metal oxide.
